(19) United States
(12) Patent Application Publication
(10) Pub. No.: US 2026/0190958 A1
(43) Pub. Date: Jul. 2, 2026

(54) SOI WAFER AND METHOD OF MANUFACTURING THE SAME

(71) Applicant: SHANGHAI SIMWINGS TECHNOLOGY CO., LTD., Shanghai (CN)

(72) Inventors: Ziwen WANG, Shanghai (CN); Wei ZHU, Shanghai (CN); Xing WEI, Shanghai (CN); Wei LI, Shanghai (CN)

(21) Appl. No.: 19/433,527

(22) Filed: Dec. 26, 2025

(30) Foreign Application Priority Data
Dec. 27, 2024 (CN) 202411963754.7

(51) Int. Cl. H10P 90/00

(52) U.S. Cl. CPC H10P 90/1916

(57) ABSTRACT

The present invention provides an SOI wafer and a method of manufacturing it. Prior to a bonding process, a plasma treatment process is performed on a second buried oxide layer on a device wafer. The duration of this plasma treatment process and plasma power used therein meet a predefined condition. The bonding process is then performed to bond a carrier wafer to the device wafer, thereby obtaining the SOI wafer. A thinning process is performed on a side of the device wafer away from the carrier wafer in the SOI wafer, without silicon islands being formed in the carrier wafer along a peripheral step or air voids developing around the center of the device wafer. SiO₂ can be formed to a reduced thickness, and surface hydrophilicity of the device wafer can be appropriately enhanced in the plasma treatment process through configuring the plasma power used therein and the duration thereof.

### CROSS-REFERENCES TO RELATED APPLICATION

This application claims the priority of Chinese patent application number 202411963754.7, filed on Dec. 27, 2024, the entire contents of which are incorporated herein by reference.

### TECHNICAL FIELD

The present invention relates to the field of integrated circuit technology and, in particular, to a silicon-on-insulator (SOI) wafer and a method of manufacturing the wafer.

### BACKGROUND

With the rapid development of integrated circuit technology, the use of bulk silicon substrates is increasingly approaching its limit of applicability to integrated circuits. In this context, silicon-on-insulator (SOI) substrates have been developed, which provide huge advantages over bulk silicon substrates, such as lower parasitic capacitance, faster operation, reduced leakage, less power consumption and eliminated latch-up. Moreover, SOI substrates are compatible with existing integrated circuit processes originally developed for bulk silicon. These account for the rapid application of SOI substrates widely in the field of integrated circuits. Therefore, the fabrication of SOI substrates with high quality is extremely important. However, an SOI substrate tends to have silicon islands scattered along its peripheral step, which can severely affect the use of the SOI substrate in subsequent integrated circuit fabrication thereon. Therefore, such silicon islands represent an issue that cannot be ignored in the fabrication of SOI substrates.

FIG. 1 shows a side view of a conventional SOI wafer. FIG. 2 shows a top view of spot A of FIG. 1 on the side of a device wafer closer to a carrier wafer. FIG. 3 shows a top view of spot B of FIG. 1 on the side of the carrier wafer closer to device wafer. When bonding strength between the device wafer 20 and the carrier wafer 10 is not high enough, air voids 201 may develop on a surface of the device wafer 20 on the side closer to the carrier wafer 10 along its peripheral edge. These air voids 201 are small and typically have a diameter of less than 0.5 mm. In the current practice, the carrier wafer 10 and the device wafer 20 are treated with plasma before they are bonded together, so that their surfaces to be bonded exhibit increased hydrophilicity, which allows the wafer to be more strongly bonded to each other. In addition to increasing the surface hydrophilicity of the device wafer 20, the plasma applied to the surface of the device wafer 20 reacts with Si to form SiO₂, resulting in more dangling bonds on the surface, which enable closer contact and hence very high bonding strength between the device wafer 20 and the carrier wafer 10 along their periphery. Nevertheless, the device wafer 20 will be more significantly affected by this if it has a thicker buried oxide layer. Consequently, during lift-off, a peripheral roll-off portion of the device wafer may partially remain on the carrier wafer along its peripheral edge, and such residuals may finally develop into silicon islands. The peripheral roll-off portion of the device wafer is a curved edge portion having a non-constant thickness that decreases outwards. In a subsequent thinning process for non-contact planarization, the oxide layer may be removed by oxidation followed by wet etching. In this process, the silicon islands 101 scattered along the peripheral step on the carrier wafer 10 tend to fall off and turn into particles attached to the surface of the SOI wafer, which, if untreated, may lead to failure of devices fabricated from the wafer, severely affecting the yield of subsequent processes.

### SUMMARY

It is an object of the present invention to provide a SOI wafer and a method of manufacturing it, which overcome the problem that silicon islands scattered in a carrier wafer along a peripheral step in an SOI wafer may lead to failure of resulting devices and therefore severely affect the yield of subsequent processes.

To this end, the present invention provides a method of manufacturing an SOI wafer, which includes:
providing a carrier wafer and a device wafer;
performing a thermal oxidation process to form a first buried oxide layer on the carrier wafer and a second buried oxide layer on the device wafer;
performing a plasma treatment process to treat the second buried oxide layer on the device wafer with plasma, thereby forming dangling bonds on a surface of the second buried oxide layer, wherein a duration of the plasma treatment process and plasma power used therein meet a predefined condition;
performing a bonding process to bond the carrier and device wafers to each other, forming the SOI wafer; and
performing a thinning process on a side of the device wafer away from the carrier wafer in the SOI wafer, without silicon islands being formed in the carrier wafer along a peripheral step or air voids developing around the center of the device wafer on its side of closer to the carrier wafer.

Optionally, the predefined condition that the duration of the plasma treatment process and the plasma power used therein meet may be expressed as:

$$[ 4000 / ( P - 90 ) + 7 ] \leq T \leq [ 3000 / ( P - 120 ) + 24 ]$$

where P represents the plasma power, which is measured in W and selected from the range of 200 W to 550 W, T denotes the duration measured in seconds.

Optionally, the plasma treatment process may use a gas, which is an oxygen gas, a nitrogen gas or a helium gas.

Optionally, before the bonding process is performed, an ion implantation process may be performed to form an implantation damage layer in the device wafer under the second buried oxide layer, which is located near an interface of the second buried oxide layer and the device wafer.

Optionally, ions implanted in the ion implantation process may be hydrogen ions or mixed hydrogen and helium ions.

Optionally, after the bonding process is performed, a lift-off process may be performed to lift off the device wafer along the implantation damage layer, thereby thinning the device wafer and resulting in the formation of a step along the periphery of the carrier wafer.

Optionally, the second buried oxide layer on the device wafer may have a thickness of 1,000 Å to 2,000 Å.

Optionally, the first buried oxide layer on the carrier wafer may have a thickness of 18,000 Å to 19,000 Å.

Optionally, both the carrier and device wafers may have an initial total thickness variation (TTV) of less than 0.5 μm.

On the basis of the same inventive concept, the present invention also provides an SOI wafer obtainable according to the method as defined above.

### BRIEF DESCRIPTION OF THE DRAWINGS

Those of ordinary skill in the art will understand that the following drawings are presented to enable a better understanding of the present invention and not intended to limit the scope thereof in any sense, in which:

FIG. 1 shows a side view of a conventional SOI wafer;

FIG. 2 shows a top view of spot A of FIG. 1 on the side of a device wafer closer to a carrier wafer;

FIG. 3 shows a top view of spot B of FIG. 1 on the side of the carrier wafer closer to device wafer;

FIG. 4 shows a flowchart of a method of manufacturing an SOI wafer according to embodiments of the present invention;

FIGS. 5 to 10 show schematic representations of structures corresponding to steps in a method of manufacturing an SOI wafer according to embodiments of the present invention; and

FIG. 11 shows a graph plotting the dependence of the presence of silicon islands in a carrier wafer that has experienced a plasma treatment process on the duration of and power used in the process according to embodiments of the present invention.

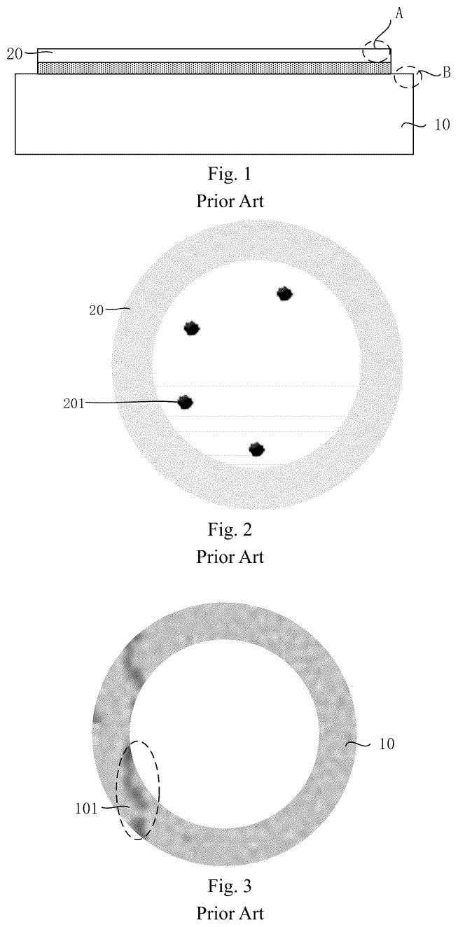

### LIST OF REFERENCE REFERRALS

10 carrier wafer; 20 device wafer;
101 silicon island; 201 air void;
11 first buried oxide layer; 21 second buried oxide layer.

### DETAILED DESCRIPTION

Objects, advantages and features of the present invention will become more apparent upon reading the following more detailed description of specific embodiments thereof in conjunction with the accompanying drawings. Note that the figures are rather simplified and not necessarily to scale, with the only intention to help explain embodiments of the invention disclosed herein in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents, and the term “or” is generally employed in the sense of “and/or”, “a number of” of “at least one” and “at least two” of “two or more”. Additionally, the use of the terms “first”, “second” and “third” herein is intended for illustration only and is not to be construed as denoting or implying relative importance, or as implicitly indicating the number of referenced items. Accordingly, defining an item with “first”, “second” or “third” is an explicit or implicit indication of the presence of one or at least two such items. When an element is referred herein to as being “disposed” on another element, this is generally intended to only mean that there is a connection, coupling, engagement or transmission relationship between the two elements, which may be either direct or indirect with one or more intervening elements, and should not be interpreted as indicating or implying a particular spatial position relationship between them. That is, the element may be located inside, outside, above, under, beside, or at any other location relative to the other element, unless the context clearly dictates otherwise. Those of ordinary skill in the art can understand the specific meanings of the above-mentioned terms herein, depending on their context.

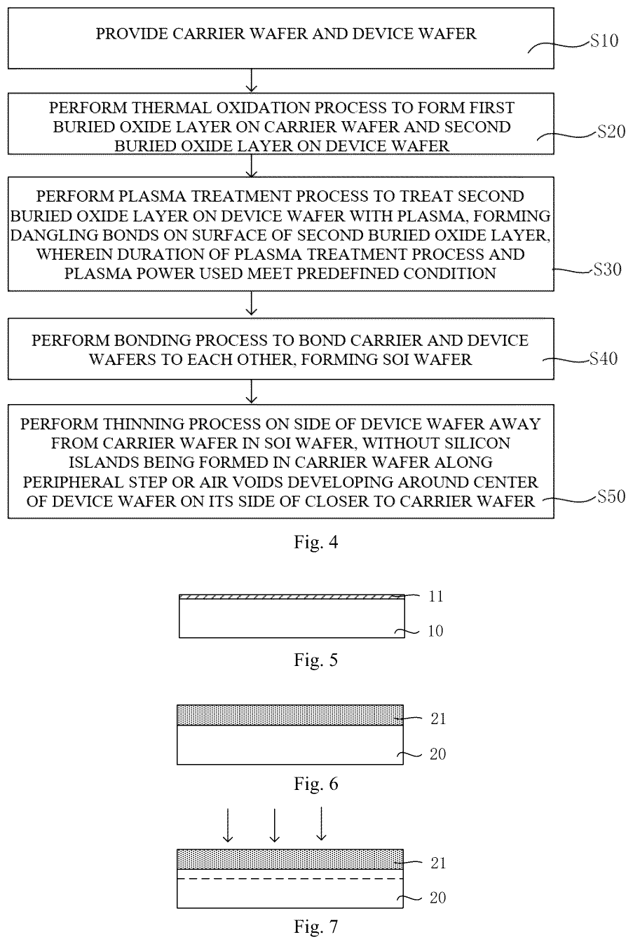

FIG. 4 shows a flowchart of a method of manufacturing an SOI wafer according to embodiments of the present invention. As shown in FIG. 4, in an embodiment of the present invention, there is provided a method of manufacturing an SOI wafer, which includes the steps of:
S10) providing a carrier wafer and a device wafer;
S20) performing a thermal oxidation process to form a first buried oxide layer on the carrier wafer and a second buried oxide layer on the device wafer;
S30) performing a plasma treatment process to treat the second buried oxide layer on the device wafer with plasma, thereby forming dangling bonds on a surface of the second buried oxide layer, wherein a duration of the plasma treatment process and plasma power used therein meet a predefined condition;
S40) performing a bonding process to bond the carrier and device wafers to each other, forming the SOI wafer; and
S50) performing a thinning process on a side of the device wafer away from the carrier wafer in the SOI wafer, without silicon islands being formed in the carrier wafer along a peripheral step or air voids developing around the center of the device wafer on its side of closer to the carrier wafer.

FIGS. 5 to 10 show schematic representations of structures corresponding to steps in a method of manufacturing an SOI wafer according to embodiments of the present invention. Specific embodiments of the present invention will be described in detail below with reference to FIGS. 5 to 10 so that the above-described objects, features and benefits thereof will become more apparent.

As shown in FIG. 5, a carrier wafer 10 is provided, which is intended to provide support for a device wafer 20 during thinning of the device wafer 20. The carrier wafer 10 may have a thickness of 773 μm to 777 μm, for example, and a total thickness variation (TTV) of less than 0.5 μm, as measured between the thickest and thinnest points at a surface of the wafer, which can be used as a measure of the wafer's thickness uniformity. A desirable TTV can ensure a uniform thickness profile of the wafer during its processing and avoid subsequent process steps and the resulting products from being otherwise affected.

As shown in FIG. 6, a device wafer 20 is provided as an object on which subsequent processes are to be carried out. It may be any substrate known to those skilled in the art for carrying semiconductor integrated circuit components, such as a bare wafer, or a wafer that has experienced epitaxial growth. In particular, the device wafer 20 may be provided as a substrate such as a silicon-on-insulator (SOI) substrate, a bulk silicon substrate, a germanium substrate, a silicon-germanium (SiGe) substrate, an indium phosphide (InP) substrate, a gallium arsenide (GaAs) substrate, or germanium-on-insulator (GeOI) substrate, amongst others. In the present embodiment, the device wafer 20 is provided as a silicon wafer. The device wafer 20 may have a thickness of 773 μm to 777 μm, for example, and a TTV of less than 0.5 μm.

With continued reference to FIGS. 5 and 6, a first buried oxide layer 11 is formed on the carrier wafer 10, and a second buried oxide layer 21 on the device wafer 20. The first buried oxide layer 11 on the carrier wafer 10 may have a thickness of, for example, 18,000 Å to 19,000 Å. The second buried oxide layer on the device wafer 20 may have a thickness of, for example, 1,000 Å to 2,000 Å.

As shown in FIG. 7, an ion implantation process is performed to form an implantation damage layer in the device wafer 20 under the second buried oxide layer 21, which is located near an interface of the second buried oxide layer 21 and the device wafer 20. In the ion implantation process, hydrogen ions, and optionally helium ions, are implanted to a depth of 0.2 μm to 0.3 μm.

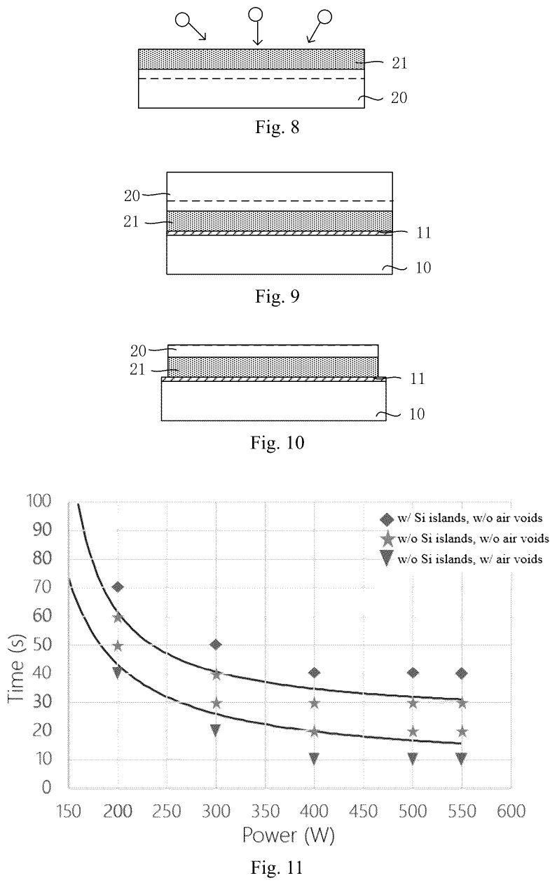

As shown in FIG. 8, a plasma treatment process is performed to treat the second buried oxide layer 21 on the device wafer 20, thereby forming dangling bonds on the treated surface of the second buried oxide layer 21, which enable stronger bonding of the device wafer 20 to the carrier wafer 10 in a subsequent bonding process. The plasma treatment process uses a gas, which is one of an oxygen gas, a nitrogen gas and an argon gas. When treated with plasma produced from an oxygen gas in the plasma treatment process, the device wafer 20 will exhibit increased surface hydrophilicity. At the same time, the second buried oxide layer 21 will be thickened, and more dangling bonds will be present thereon, which can help increase bonding strength between the device wafer 20 and the carrier wafer 10 in the subsequent bonding process. However, as a consequence of the thickening of the second buried oxide layer 21, closer contact will occur between the device wafer 20 and the first buried oxide layer 11 of the carrier wafer 10 along a peripheral step thereon in the bonding process, leading to higher bonding strength between the device wafer 20 and the carrier wafer 10 along their periphery and hence possible subsequent formation of silicon islands in the carrier wafer along the peripheral step 10 during the fabrication of the SOI wafer. A good tradeoff can be made between higher bonding strength and prevented formation of silicon islands by adjusting process parameters of the plasma treatment process on the device wafer 20. For example, less power may be used in the plasma treatment process, or the process itself may be carried out for a shorter period of time, to reduce the bonding strength along the peripheral step in the SOI wafer and counteract the thickening of the second buried oxide layer, such that fewer or even no silicon islands are formed. According to the present embodiment, the formation of silicon islands in the carrier wafer along the peripheral step in the SOI wafer and the development of air voids around the center of the device wafer on its side closer to the carrier wafer can be advantageously avoided. The duration of the plasma treatment process and plasma power used therein meet the following predefined condition:

$$[ 4000 / ( P - 90 ) + 7 ] \leq T \leq [ 3000 / ( P - 120 ) + 24 ] ,$$

where P represents the plasma power, which is measured in W and selected from the range of 200 W to 550 W, and T denotes the duration measured in seconds (s). That is, according to the present embodiment, when the duration of the plasma treatment process and the plasma power used therein satisfy the predefined condition, it can be ensured that no silicon islands are formed along the peripheral step on the carrier wafer in the SOI wafer and that no air voids develop around the center of the device wafer on its side closer to the carrier wafer.

As shown in FIG. 9, a bonding process is performed to bond the carrier wafer 10 to the device wafer 20, thereby forming the SOI wafer.

As shown in FIG. 10, a lift-off process is performed to lift the device wafer 20 along the implantation damage layer, thereby reducing its thickness. Because of reduced bonding strength along the peripheral step in the SOI wafer, at the same time as the portion of the device wafer 20 above the implantation damage layer is lifted, a portion of the device wafer 20 along the periphery of the SOI wafer is also lifted. As a result, a step is defined between the carrier wafer 10 and the device wafer 20 along the periphery of the SOI wafer, without the risk of forming silicon islands in the carrier wafer 10 along the peripheral step.

After the lift-off process is completed, a thinning process is performed to thin the device wafer 20 on its side away from the carrier wafer 10, without the risk of formation of silicon islands in the carrier wafer 10 along the peripheral step or development of air voids (or picots) around the center of the device wafer 20 on the side closer to the carrier wafer 10. The thinning process may include first forming an oxide layer on the side of the device wafer 20 away from the carrier wafer 10 by oxidation and then removing the oxide layer by wet etching using a solution containing hydrofluoric acid. The thinning process can be conducted without the risk of forming silicon islands in the carrier wafer 10 along the peripheral step.

As shown in FIG. 10, in embodiments of the present invention, there is also provided an SOI wafer obtainable according to any of the methods as defined above, which includes a carrier wafer 10 and a device wafer 20 positioned on and bonded to the carrier wafer 10. The carrier wafer 10 is used to support the device wafer 20, and a first buried oxide layer 11 and a second buried oxide layer 21 are formed in the carrier wafer 10 and the device wafer 20, respectively. The carrier wafer 10 and the device wafer 20 together define a step along their periphery. There are no silicon islands in the carrier wafer 10 along the peripheral step and no air voids around the center of a surface of the device wafer 20 on its side closer to the carrier wafer.

The inventors have conducted an experiment for investigating the influence of a plasma treatment process on the presence of silicon islands and air voids in an SOI wafer. The experiment included five groups each consisting of four subgroups, a total of 20 subgroups. The groups were treated with plasma power at respective different levels of 550 W, 500 W, 400 W, 300 W and 200 W, each with the same level of power. In each group, the subgroups were treated with plasma for different respective durations of time. In each of the 550-W, 500-W and 400-W groups, the durations were respectively 10 s, 20 s, 30 s and 40 s. Generally, a plasma treatment process was carried out at a higher level of power for a shorter duration of time, in order to result in satisfactory bonding strength between the carrier wafer 10 and the device wafer 20. The subgroups in the 300-W group were treated respectively for 20 s, 30 s, 40 s and 50 s, and the 200-W subgroups respectively for 40 s, 50 s, 60 s and 70 s. In the experiment, for example, each carrier wafer 10 contained a 19,000-Å thick first buried oxide layer 11, and each device wafer 20 contained a 1,000-Å thick second buried oxide layer 21. The steps and parameters in the experiment were the same as have been described above in connection with the foregoing embodiments. Repeated description thereof is omitted herein.

| | | | Thickness of Resulting | | |
|---|---|---|---|---|---|
| | Power | Duration | Second Buried Oxide | Density of | Air Voids |
| Subgroup | (W) | (s) | Layer (Å) | Silicon Islands | Observed |
| 1-1 | 550 | 10 | 16 | Zero | Yes |
| 1-2 | 550 | 20 | 42 | Zero | No |
| 1-3 | 550 | 30 | 60 | Zero | No |
| 1-4 | 550 | 40 | 65 | High | No |
| 2-1 | 500 | 10 | 18 | Zero | Yes |
| 2-2 | 500 | 20 | 39 | Zero | No |
| 2-3 | 500 | 30 | 57 | Zero | No |
| 2-4 | 500 | 40 | 62 | High | No |
| 3-1 | 400 | 10 | 15 | Zero | Yes |
| 3-2 | 400 | 20 | 32 | Zero | No |
| 3-3 | 400 | 30 | 49 | Zero | No |
| 3-4 | 400 | 40 | 58 | Medium | No |
| 4-1 | 300 | 20 | 21 | Zero | Yes |
| 4-2 | 300 | 30 | 42 | Zero | No |
| 4-3 | 300 | 40 | 53 | Zero | No |
| 4-4 | 300 | 50 | 64 | Medium | No |
| 5-1 | 200 | 40 | 47 | Zero | Yes |
| 5-2 | 200 | 50 | 55 | Zero | No |
| 5-3 | 200 | 60 | 61 | Zero | No |
| 5-4 | 200 | 70 | 69 | Low | No |

FIG. 11 shows a graph plotting the dependence of the presence of silicon islands and air voids in and on a carrier wafer that has experienced a plasma treatment process on the duration of and power used in the process according to embodiments of the present invention. The graph of FIG. 11 is plotted from the experimental data. In FIG. 11, the abscissa represents power, measured in watts (W), and the ordinate represents time, measured in seconds (s). Subgroups identified with silicon islands and picots (air voids) are marked with red diamonds, those without silicon islands and picots (air voids) marked with green pentagrams, and those without silicon islands but with picots (air voids) marked with red triangles. As can be seen from the experimental results shown in Table 1 and FIG. 11, the SOI wafers of Subgroups 1-4 and 2-4 are associated with the most significant presence silicon islands along their peripheral steps, and those of Subgroups 3-4, 4-4 and 5-4 each show a reduced density of silicon islands along its peripheral step. Thus, it can be concluded that an SOI wafer treated with a lower level of plasma power has a lower density of silicon islands along its peripheral step. Moreover, in each group treated with the same level of plasma power, the subgroup treated for the shortest duration is most likely to be observed with air voids. Accordingly, a tradeoff can be found between reduced formation of silicon islands and less presence of air voids for a device wafer 20 by performing a plasma treatment process thereon whose process parameters are tuned, for example, through reducing the plasma power used and/or the plasma treatment duration, so that bonding strength is appropriately reduced along the peripheral step in the SOI wafer and that a thinner second buried oxide layer is formed. In this way, the formation of silicon islands can be mitigated, or even eliminated. However, air voids may be present in the treated SOI wafer if the power used is too low or the duration is too short. According to embodiments of the present invention, the duration and plasma power of such a plasma treatment process satisfy the following predefined condition:

$$[ 4000 / ( P - 90 ) + 7 ] \leq T \leq [ 3000 / ( P - 120 ) + 24 ]$$

where P represents the plasma power, which is measured in W and selected from the range of 200 W to 550 W, and T denotes the duration measured in seconds (s). That is, according to the present invention, when the duration of the plasma treatment process and the plasma power used therein satisfy the predefined condition, desired bonding strength can be obtained between the device and carrier wafer without the formation of silicon islands. In other words, neither air voids nor silicon islands will be present in the resulting SOI wafer.

In summary, embodiments of the present invention provide a method of manufacturing an SOI wafer, in which a thermal oxidation process is first performed to form a first buried oxide layer on a carrier wafer and a second buried oxide layer on a device wafer, and a plasma treatment process is then performed to treat the second buried oxide layer on the device wafer with plasma, thereby forming dangling bonds on a surface of the second buried oxide layer. The duration of the plasma treatment process and plasma power used therein meet a predefined condition. Subsequently, a bonding process is performed to bond the carrier and device wafers to each other, forming the SOI wafer. Finally, a thinning process is performed on a side of the device wafer away from the carrier wafer in the SOI wafer, without silicon islands being formed in the carrier wafer along a peripheral step or air voids developing around the center of the device wafer on its side of closer to the carrier wafer. According to the present invention, the formation of silicon islands in the carrier wafer along the peripheral step and the development of air voids around the center of the device wafer on the side closer to the carrier wafer can be prevented through configuring the plasma power used in, and the duration of, the plasma treatment process so that they satisfy the predefined condition. In this way, SiO₂ can be formed to a reduced thickness, and surface hydrophilicity of the device wafer can be appropriately enhanced in the plasma treatment process, preventing the formation of silicon islands in the carrier wafer along the peripheral step, which may otherwise develop into particles attached to the surface of the carrier wafer in subsequent processes. These particles can lead to failure of the resulting devices, severely affecting the yield of subsequent processes.

Further, it will be recognized that while the invention has been described above with respect to preferred embodiments, it is not intended to be limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent changes and modifications made to the foregoing embodiments based on the substantive disclosure of the invention without departing from the scope thereof fall within this scope.

What is claimed is:

1. A method of manufacturing a silicon-on-insulator wafer, comprising:
providing a carrier wafer and a device wafer;
performing a thermal oxidation process to form a first buried oxide layer on the carrier wafer and a second buried oxide layer on the device wafer;
performing a plasma treatment process to treat the second buried oxide layer on the device wafer with plasma, thereby forming dangling bonds on a surface of the second buried oxide layer, wherein a duration of the plasma treatment process and plasma power used therein satisfy a predefined condition;
performing a bonding process to bond the carrier wafer and the device wafer, forming the silicon-on-insulator wafer; and
performing a thinning process on a side of the device wafer away from the carrier wafer in the silicon-on-insulator wafer, without silicon islands being formed in the carrier wafer along a peripheral step or air voids developing around a center of the device wafer on a side thereof closer to the carrier wafer.

2. The method according to claim 1, wherein the predefined condition that the duration of the plasma treatment process and the plasma power used therein meet is expressed as:
$$[ 4000 / ( P - 90 ) + 7 ] ⩽ T ⩽ [ 3000 / ( P - 120 ) + 24 ]$$
where P represents the plasma power, which is measured in W and selected from the range of 200 W to 550 W, T denotes the duration measured in seconds.

3. The method according to claim 1, wherein the plasma treatment process uses a gas, which is an oxygen gas, a nitrogen gas or a helium gas.

4. The method according to claim 1, wherein before the bonding process is performed, an ion implantation process is performed to form an implantation damage layer in the device wafer under the second buried oxide layer, which is located near an interface of the second buried oxide layer and the device wafer.

5. The method according to claim 4, wherein ions implanted in the ion implantation process are hydrogen ions or mixed hydrogen and helium ions.

6. The method according to claim 4, wherein after the bonding process is performed, a lift-off process is performed to lift off the device wafer along the implantation damage layer, thereby thinning the device wafer and resulting in the formation of a step along the periphery of the carrier wafer.

7. The method according to claim 1, wherein the second buried oxide layer on the device wafer has a thickness of 1,000 Å to 2,000 Å.

8. The method according to claim 1, wherein the first buried oxide layer on the carrier wafer has a thickness of 18,000 Å to 19,000 Å.

9. The method according to claim 1, wherein an initial total thickness variation of both the carrier wafer and the device wafer is less than 0.5 μm.

10. A silicon-on-insulator wafer, characterized by being prepared using the method according to claim 1.
